(19) United States
(12) Patent Application Publication
(10) Pub. No.: US 2026/0201554 A1
(43) Pub. Date: Jul. 16, 2026

(54) CLEANING METHOD AND FILM-FORMING APPARATUS

(71) Applicant: Tokyo Electron Limited, Tokyo (JP)

(72) Inventor: Hiroaki ASHIZAWA, Yamanashi (JP)

(21) Appl. No.: 19/566,359

(22) Filed: Mar. 13, 2026

Related U.S. Application Data
(63) Continuation of application No. PCT/JP2024/032557, filed on Sep. 11, 2024.

(30) Foreign Application Priority Data
Sep. 25, 2023 (JP) 2023-161608

(51) Int. Cl. C23C 16/44; B08B 9/00; C23C 16/06; C23C 16/40; C23C 16/52

(52) U.S. Cl. CPC C23C 16/4405; B08B 9/00; C23C 16/06; C23C 16/403; C23C 16/405; C23C 16/52

(57) ABSTRACT

A cleaning method for a film-forming apparatus is provided. The film-forming apparatus includes a film-forming-raw-material-gas supply source, a film-forming-reaction-gas supply source, a first-cleaning-gas supply source, a second-cleaning-gas supply source, a stage provided in a processing chamber and configured to receive a substrate and to be elevatable, and a cap member provided in the processing chamber and facing the stage to form a processing space. The cleaning method includes forming a film over a substrate by supplying, to the processing space, a film-forming raw material gas from the film-forming-raw-material-gas supply source and a film-forming reaction gas from the film-forming-reaction-gas supply source; and cleaning an interior of the processing space by transferring the substrate out after the formation of the film, and supplying, to the processing space, a first cleaning gas from the first-cleaning-gas supply source and a second cleaning gas from the second-cleaning-gas supply source, in an alternating manner.

### CROSS-REFERENCE TO RELATED APPLICATIONS

This application is a continuation application of International Application No. PCT/JP2024/032557, filed on September 11, 2024, and designated the U.S., which is based upon and claims priority to Japanese Patent Application No. 2023-161608, filed on September 25, 2023, the entire contents of which are incorporated herein by reference.

### BACKGROUND

### 1. FIELD OF THE INVENTION

The present disclosure relates to a cleaning method and a film-forming apparatus.

### 2. Description of the Related Art

For example, PCT Japanese Translation Patent Publication No. 2019-519918 proposes to perform atomic layer etching (ALE) on a substrate, thereby etching a target film at a 1 Å level without damaging the bottom layer on the substrate.

### SUMMARY

One aspect of the present disclosure is a cleaning method for a film-forming apparatus including a film-forming raw material gas supply source, a film-forming reaction gas supply source, a first cleaning gas supply source, a second cleaning gas supply source, a stage that is provided in a processing chamber and is configured to receive a substrate and to be elevatable, and a cap member that is provided in the processing chamber and faces the stage to form a processing space. The cleaning method includes: forming a film over the substrate by supplying, to the processing space, a film-forming raw material gas from the film-forming raw material gas supply source and a film-forming reaction gas from the film-forming reaction gas supply source; and cleaning an interior of the processing space by transferring the substrate out of the processing chamber after the formation of the film, and supplying, to the processing space, a first cleaning gas from the first cleaning gas supply source and a second cleaning gas from the second cleaning gas supply source, in an alternating manner.

### BRIEF DESCRIPTION OF DRAWINGS

FIG. 1 is a diagram illustrating an example of a cycle cleaning method according to an embodiment.

FIG. 2 is a diagram illustrating an example of a chemical reaction of first and second cleaning gases according to the embodiment.

FIG. 3 is a table indicating examples of combinations of the first and second cleaning gases according to the embodiment.

FIG. 4 is a table indicating examples of combinations of the first and second cleaning gases according to the embodiment.

FIG. 5 is a table indicating examples of combinations of the first and second cleaning gases according to the embodiment.

FIG. 6 is a table indicating examples of combinations of the first and second cleaning gases according to the embodiment.

FIG. 7 is a diagram illustrating a configuration example of a film-forming apparatus according to an embodiment.

FIG. 8 is a flowchart illustrating an example of a processing method in the film-forming apparatus according to the embodiment.

FIG. 9 is a flowchart illustrating an example of a film-forming process of FIG. 8.

FIG. 10 is a flowchart illustrating an example of a cleaning process of FIG. 8.

### DETAILED DESCRIPTION OF THE DISCLOSURE

The present disclosure provides a technique that can clean parts in a film-forming apparatus while suppressing damage to the parts.

Hereinafter, embodiments of the present disclosure will be described with reference to the drawings. In the drawings, the same components are denoted by the same reference signs, and thus duplicate descriptions may be omitted.

### Cleaning of high-k material

After film-forming processing in a film-forming apparatus, for removing a film and reaction products adhering to the interior of a chamber, the interior of the chamber is cleaned by supplying an existing cleaning gas, such as ClF₃ or the like, into the chamber. For enabling formation of a high-k film, the temperature of the inner wall of the chamber or the temperature of a stage needs to be a high temperature of about 500°C to about 700°C. This causes a problem with exceeding the heat resistant temperatures of the chamber and parts in the chamber during cleaning. In particular, in the case of a single-wafer type processing apparatus, it is difficult to perform dry cleaning of a high-k material with an existing cleaning gas, such as ClF₃ or the like.

Therefore, one possible measure when forming the high-k material in the single-wafer type processing apparatus is to previously attach a liner configured to cover the interior of the chamber, and replace the liner when particles or the like are formed. However, the liner needs to be replaced every time particles are adhered, which is significantly time-consuming for releasing the chamber to the atmosphere and performing replacement of the liner. In addition, even if the liner is disposed, a film-forming gas tends to circulate in the film-forming apparatus, thereby disadvantageously forming a film in a place where the liner is not disposed. Therefore, just disposing the liner is insufficient in terms of productivity and cleaning performance. Also, the greater the amount of particles adhering to the liner, the sooner the liner must be replaced, which leads to a reduction in productivity.

In recent years, ALE has garnered significant attention. With this technique, a raw material gas and a reaction gas are supplied in an alternating manner to a logic device on a substrate, performing etching at a rate of about 1 Å per cycle. It is used, for example, to etch an ultrathin oxide film or a high-k film on the substrate.

### Cleaning method

The present embodiment provides a cleaning method of cleaning a high-k film or the like adhering to the interior of a processing chamber by supplying two different cleaning gases in an alternating manner. Specifically, the present embodiment provides an ALE-like cleaning method (hereinafter referred to as cycle cleaning) for the interior of the processing chamber of the film-forming apparatus by supplying a first cleaning gas and a second cleaning gas in an alternating manner after formation of a high-k film or a metal film. According to this method, it is possible to clean the interior of the processing chamber while suppressing damage to parts in the processing chamber.

Alumina (Al₂O₃), zirconium oxide (ZrO₂), hafnium oxide (HfO₂), or the like is used as the high-k material. In general, when adhering to the interior of the processing chamber of the film-forming apparatus, these materials cannot be removed with an existing cleaning gas, such as ClF₃ or the like.

By use of a desired combination of the first cleaning gas and the second cleaning gas, it is possible to clean the interior of the processing chamber by performing the cycle cleaning of supplying the first cleaning gas and the second cleaning gas in an alternating manner.

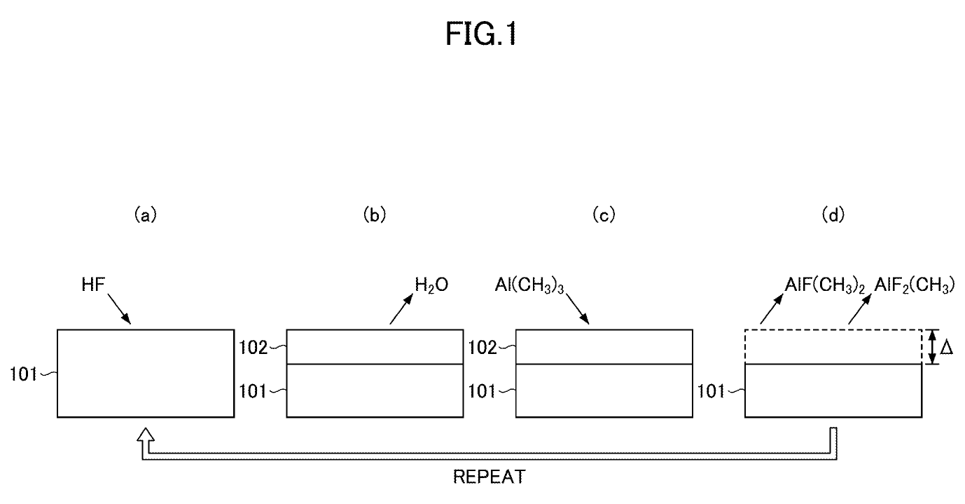

FIG. 1 is a diagram illustrating an example of the cycle cleaning. Specifically, (a) of FIG. 1 illustrates a target film 101 of an alumina film as an example of the high-k material adhering to the film-forming apparatus. When the alumina film is formed in the film-forming apparatus, the alumina film and the reaction products adhere to the inner wall of the processing chamber and the parts in the processing chamber.

In this state, by supplying an HF gas (hydrogen fluoride gas) into the processing chamber as the first cleaning gas, as illustrated in (b) of FIG. 1, a modified layer 102 is formed in which the surface of the target film 101 is modified to AlF₃. The chemical reaction at this time is Al₂O₃+6HF→2AlF₃+3H₂O. As a result, the surface of the target film 101 turns into the modified layer 102 of AlF₃, and H₂O volatilizes.

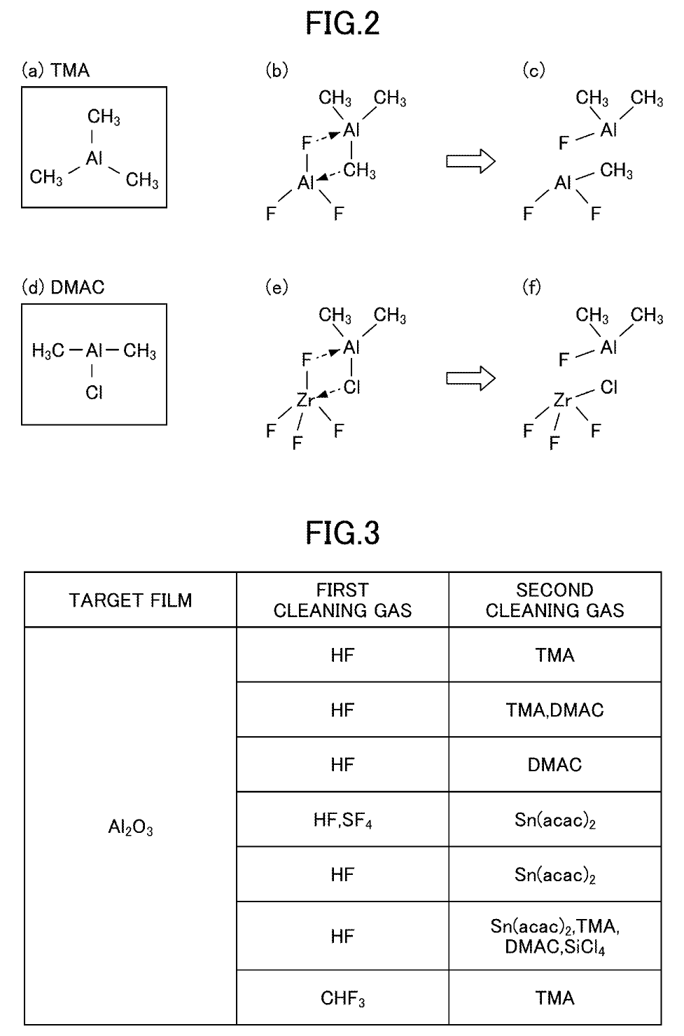

Next, by supplying a TMA (trimethylaluminum: Al(CH₃)₃) gas illustrated in (a) of FIG. 2 as the second cleaning gas, the modified layer 102 of AlF₃ is etched. At this time, as illustrated in (b) of FIG. 2, the TMA gas extracts one F from the AlF₃ of the modified layer 102, resulting in AlF(CH₃)₂ illustrated in (c) of FIG. 2. The AlF(CH₃)₂ volatilizes as illustrated in (d) of FIG. 1. Also, as illustrated in (c) of FIG. 2, the remaining CH₃ of the TMA gas is bonded to the modified layer 102 (AlF₂) from which one F has been extracted, resulting in AlF₂(CH₃). AlF₂(CH₃) volatilizes as illustrated in (d) of FIG. 1. Thus, the AlF₃ of the modified layer 102 is etched (cleaned).

By supplying, as the first cleaning gas, an HF gas (hydrogen fluoride gas) to the target film 101 of a zirconium oxide film, which is another high-k material, the modified layer 102 is formed in which the surface of the target film 101 is modified to ZrF₄.

By supplying, as the second cleaning gas, a DMAC (dimethylaluminum chloride: AlCl(CH₃)₂) gas illustrated in (d) of FIG. 2, the modified layer 102 of ZrF₄ is etched. At this time, as illustrated in (e) of FIG. 2, the DMAC gas extracts one F from the ZrF₄ of the modified layer 102, resulting in AlF(CH₃)₂ illustrated in (f) of FIG. 2, followed by volatilizing. The remaining Cl of the DMAC gas is bonded to the modified layer 102 (ZrF₃) from which one F has been extracted, resulting in ZrF₃Cl, followed by volatilizing. Thus, the ZrF₄ of the modified layer 102 is etched (cleaned).

The etching level Δ of the surface layer of the target film 101 illustrated in (d) of FIG. 1 at one time is equivalent to one layer at an atomic layer level, i.e., about 1 Å. In such an ALE-like cycle cleaning, etching can be performed while controlling the internal temperature of the processing chamber of the film-forming apparatus to be about 200°C to about 250°C. Therefore, there is an advantage that the interior of the processing chamber can be cleaned not only in a batch type film-forming apparatus but also in a single-wafer type film-forming apparatus.

For etching the film adhering to the processing chamber or the like to a predetermined thickness, a cycle of (a) to (d) of FIG. 1 is repeated a predetermined number of times by supplying an HF gas and a TMA gas in an alternating manner. As a result, the cycle cleaning is performed, and the film having a thickness corresponding to the number of repeated cycles is etched, thereby cleaning the interior of the processing chamber. As described above, in the cycle cleaning of the present embodiment, the ALE technique is utilized not for etching of the substrate but for cleaning of the high-k film or metal film adhering to the interior of the processing chamber of the film-forming apparatus.

### Combination of cleaning gases

A combination of the first cleaning gas and the second cleaning gas for cleaning the film-forming apparatus varies with the type of a film to be formed over the substrate in the film-forming apparatus (cleaning target film).

When an oxide film of alumina, hafnium oxide, zirconium oxide, or IGZO is formed over the substrate as an example of the high-k film, the first cleaning gas is a gas including fluorine.

For example, in a case in which an alumina film is formed over the substrate, the target film in cleaning the film-forming apparatus is the alumina film, and examples of combinations of the first cleaning gas and the second cleaning gas are indicated in FIG. 3.

When the first cleaning gas is an HF gas, the second cleaning gas may be a TMA gas, a DMAC gas, an Sn(acac)₂ gas, a gas mixture of a TMA gas and a DMAC gas, or a gas mixture of a TMA gas, a DMAC gas, an Sn(acac)₂ gas, and an SiCl₄ gas. When the first cleaning gas is a CHF₃ gas, the second cleaning gas may be a TMA gas. When the first cleaning gas is a gas mixture of an HF gas and an SF₄ gas, the second cleaning gas may be an Sn(acac)₂ gas.

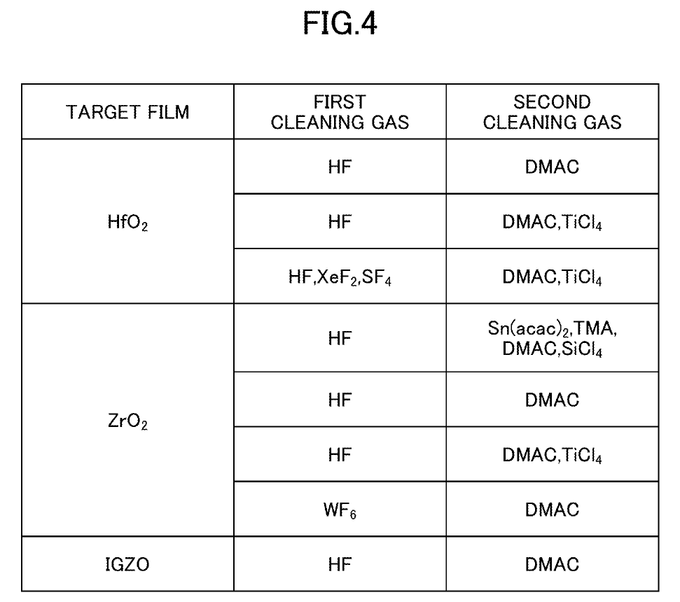

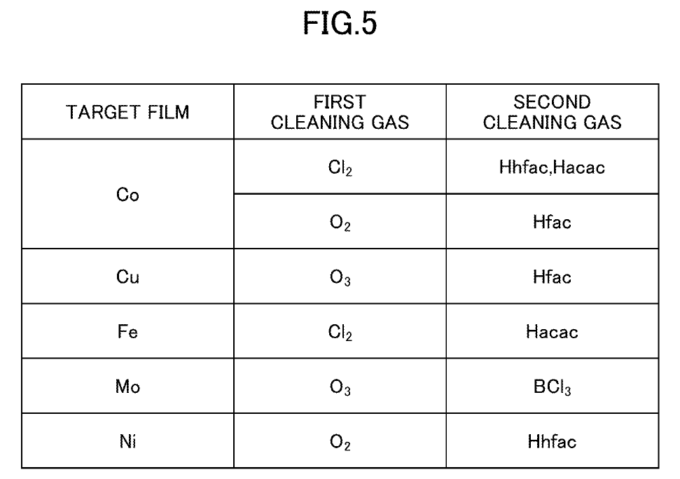

FIG. 4 indicates examples of combinations of the first cleaning gas and the second cleaning gas in cleaning the film-forming apparatus in a case in which a hafnium oxide film, a zirconium oxide film, or an IGZO film is formed over the substrate.

In the case in which the hafnium oxide film is formed over the substrate, when the first cleaning gas is an HF gas, the second cleaning gas may be a DMAC gas, or a gas mixture of a DMAC gas and a TiCl₄ gas. When the first cleaning gas is a gas mixture of an HF gas, an XeF₂ gas, and an SF₄ gas, the second cleaning gas may be a gas mixture of a DMAC gas and a TiCl₄ gas.

In the case in which the zirconium oxide film is formed over the substrate, when the first cleaning gas is an HF gas, the second cleaning gas may be a DMAC gas, a gas mixture of a DMAC gas and a TiCl₄ gas, or a gas mixture of a DMAC gas, a TMA gas, an Sn(acac)₂ gas, and an SiCl₄ gas. When the first cleaning gas is a WF₆ gas, the second cleaning gas may be a DMAC gas.

In the case in which the IGZO film is formed over the substrate, the first cleaning gas may be an HF gas, and the second cleaning gas may be a DMAC gas.

FIG. 5 indicates examples of combinations of the first cleaning gas and the second cleaning gas in cleaning the film-forming apparatus in a case in which a metal film of Co, Cu, Fe, Mo, or Ni is formed over the substrate.

In the case in which the above metal film is formed, the first cleaning gas is a gas including oxygen or a gas including chlorine.

In the case in which the Co film is formed over the substrate, when the first cleaning gas is a Cl₂ gas, the second cleaning gas may be a gas mixture of an Hhfac gas and an Hacac gas. When the first cleaning gas is an O₂ gas, the second cleaning gas may be an Hfac gas.

In the case in which the Cu film is formed over the substrate, the first cleaning gas may be an O₃ gas, and the second cleaning gas may be an Hfac gas.

In the case in which the Fe film is formed over the substrate, the first cleaning gas may be a Cl₂ gas, and the second cleaning gas may be an Hacac gas.

In the case in which the Mo film is formed over the substrate, the first cleaning gas may be an O₃ gas, and the second cleaning gas may be a BCl₃ gas.

In the case in which the Ni film is formed over the substrate, the first cleaning gas may be an O₂ gas, and the second cleaning gas may be an Hhfac gas.

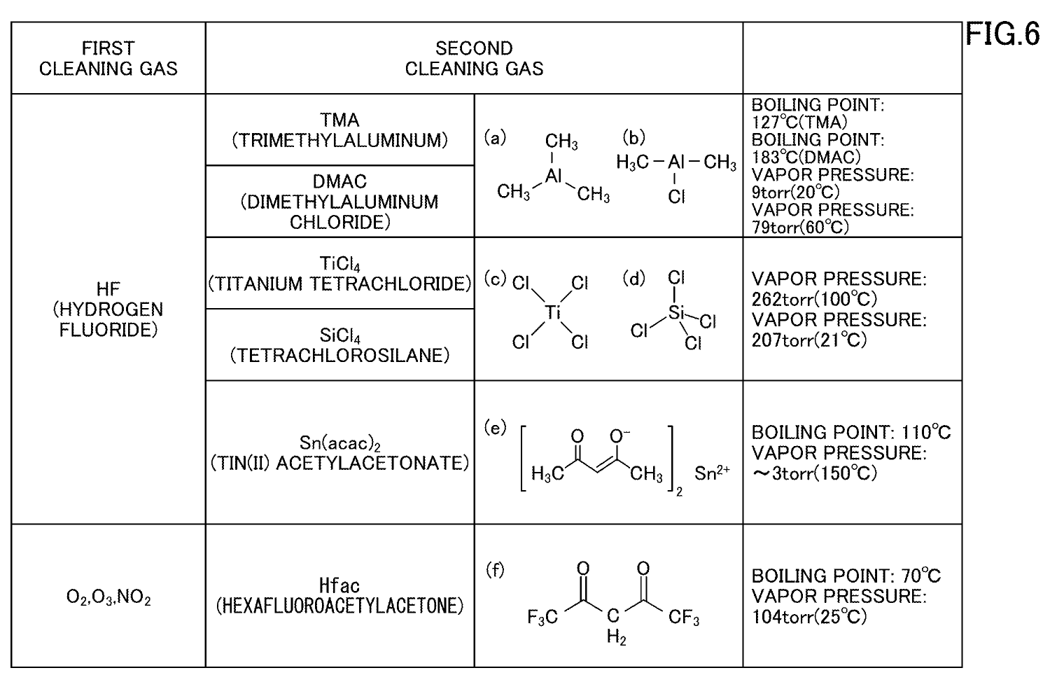

FIG. 6 is a table indicating examples of combinations of the first and second cleaning gases according to the embodiment. FIG. 6 indicates typical examples of the second cleaning gas and their chemical formulae when an HF gas or a gas including oxygen (O₂, O₃, or NO₂) is used as the first cleaning gas.

With an HF gas being used as the first cleaning gas, the chemical formula of a TMA gas, i.e. an example of the second cleaning gas, is indicated in (a) and the chemical formula of a DMAC gas, i.e. an example of the second cleaning gas, is indicated in (b). Also, with an HF gas being used as the first cleaning gas, the chemical formula of a TiCl₄ gas, i.e. an example of the second cleaning gas, is indicated in (c), the chemical formula of an SiCl₄ gas, i.e. an example of the second cleaning gas, is indicated in (d), and the chemical formula of an Sn(acac)₂ gas, i.e. an example of the second cleaning gas, is indicated in (e).

With the gas including oxygen (O₂, O₃, or NO₂) being used as the first cleaning gas, the chemical formula of an Hfac gas, i.e. an example of the second cleaning gas, is indicated in (f).

In the case in which the gas including oxygen (O₂, O₃, or NO₂) is used as the first cleaning gas, when an Hfac gas is used as the second cleaning gas, it is possible to perform both etching of the oxide in the processing chamber and cleaning of the piping of a gas line for supplying a precursor of the film-forming raw material.

FIG. 6 also indicates the boiling point, vapor pressure, and the like of each gas. When a fill tank configured to temporarily store a gas is provided in a gas line of the film-forming apparatus described below, a gas is stored in the fill tank at a pressure equal to or higher than a predetermined pressure, and the stored gas can be supplied into the processing chamber at the pressure equal to or higher than the predetermined pressure. Thus, the cleaning gases can be supplied at a high speed, thereby performing the cycle cleaning at a high speed, in which the plurality of cleaning gases are supplied in an alternating manner. Therefore, a gas having a low vapor pressure is not suitable for the cycle cleaning.

For example, TMA has a vapor pressure of 760 Torr at a boiling point of 127°C, and a vapor pressure of 9 Torr at 20°C. Therefore, by heating TMA to about 40°C to about 50°C, it is possible to obtain TMA having a vapor pressure of about 100 Torr. Therefore, even if the temperature of TMA is not increased to the boiling point of 127°C, TMA can be turned into a state having a vapor pressure of 100 Torr to 200 Torr.

Similarly, DMAC has a vapor pressure of 760 Torr at a boiling point of 183°C, and a vapor pressure of 79 Torr at 60°C. Therefore, by heating DMAC to about 65°C to about 70°C, it is possible to obtain DMAC having a vapor pressure of about 100 Torr. Therefore, even if the temperature of DMAC is not increased to the boiling point of 183°C, DMAC can be turned into a state having a vapor pressure of 100 Torr to 200 Torr.

A high vapor pressure is necessary for supplying the stored gas from the fill tank provided in the gas line of the film-forming apparatus into the processing chamber at a high speed. In the case of the TMA gas having the boiling point of 127°C or the DMAC gas having the boiling point of 183°C, when TMA or DMAC in a liquid form is heated to about 100°C and turned into a gaseous state, the vapor pressure is expected to be about 100 Torr. In this manner, TMA or DMAC is turned into a gaseous state and temporarily stored in the fill tank at a relatively high vapor pressure, and a relatively large amount of gas is supplied at a high speed (referred to as fill flow). This enables high-speed gas substitution.

Similarly, TiCl₄, SiCl₄, Sn(acac)₂, and Hfac indicated in FIG. 6 are turned into a gaseous state and temporarily stored in the fill tank at a relatively high vapor pressure, thereby achieving the fill flow of supplying a relatively large amount of gas at a high speed.

This enables a high-speed cycle cleaning by switching the first cleaning gas and the second cleaning gas at a high speed and supplying these gases in an alternating manner. Using the fill flow, the period per cycle when repeatedly supplying the first cleaning gas and the second cleaning gas in an alternating manner can be reduced to 2 seconds or less. For example, in the cycle cleaning using the fill flow, one cycle is 0.5 seconds to 1 second. That is, 1 Å etching (cleaning) can be performed in 0.5 seconds to 1 second. At maximum, 2 Å etching can be performed in 1 second. When the 2 Å etching is performed in 1 second, a film of 7,200 Å can be removed through etching in 1 hour, and a film of 1.4 μm can be removed through etching in 2 hours.

### Film-forming apparatus

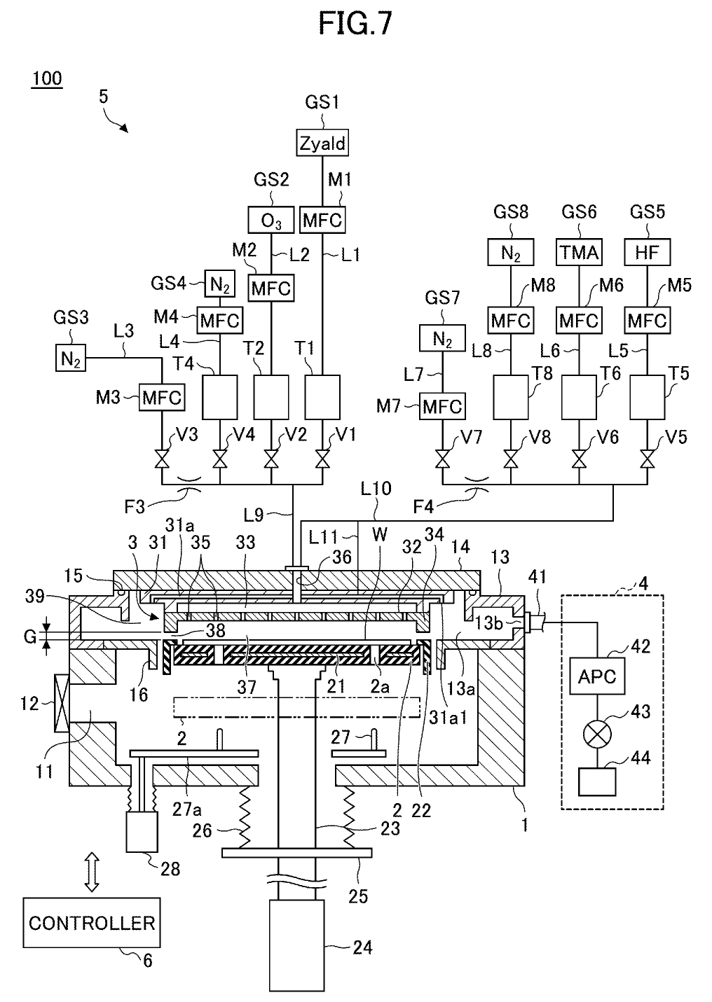

Next, a configuration example of a film-forming apparatus configured to perform the cleaning method according to the embodiment will be described with reference to FIG. 7. FIG. 7 is a diagram illustrating the configuration example of the film-forming apparatus according to the embodiment.

A film-forming apparatus 100 is configured to supply a Zyald ((C₅H₅)Zr[N(CH₃)₂]₃) gas, i.e., an example of the film-forming raw material gas, and an O₃ gas, i.e., an example of the film-forming reaction gas, to a substrate W, such as a wafer or the like, thereby forming a zirconium oxide film, i.e., an example of the high-k film, over the substrate W. The zirconium oxide may include ZrO and ZrO₂. The film-forming apparatus 100 is, for example, formed by an ALD (Atomic Layer Deposition) apparatus or the like.

The film-forming apparatus 100 includes a processing chamber 1, a stage 2, a shower head 3, a gas exhauster 4, a gas supply 5, and a controller 6. The processing chamber 1 is formed of a metal, such as aluminum or the like, and has a substantially cylindrical shape. A transfer outlet 11 for transferring in or out the substrate W is formed in a side wall of the processing chamber 1, and the transfer outlet 11 can be opened and closed by a gate valve 12. An annular gas exhaust duct 13 having a rectangular cross section is provided on the body of the processing chamber 1. A slit 13a is formed in the gas exhaust duct 13 along the inner circumferential surface. A gas exhaust port 13b is formed in the outer wall of the gas exhaust duct 13. A top wall 14 is provided on the top surface of the gas exhaust duct 13 to close the top opening of the processing chamber 1. A space between the top wall 14 and the gas exhaust duct 13 is airtightly sealed by a seal ring 15. A partition member 16 vertically partitions the interior of the processing chamber 1 when the stage 2 and a cover member 22 are raised to the film-forming position. The stage 2 and the cover member 22 in FIG. 7 are at the film-forming position.

The stage 2 is configured to horizontally support the substrate W in the processing chamber 1 and to be elevatable. The stage 2 has a disk shape having a size corresponding to the substrate W, and is supported by a supporting member 23. The stage 2 is formed of a ceramic material, such as aluminum nitride (AlN) or the like, or a metal material, such as aluminum, a nickel-based alloy, or the like, and a heater 21 configured to heat the substrate W is embedded therein. The heater 21 is configured to generate heat by supply of power from a heater power supply (not shown). The output of the heater 21 is controlled by a temperature signal from a thermocouple (not shown) provided near the top surface (substrate-receiving surface) of the stage 2, thereby controlling the substrate W to a predetermined temperature.

The stage 2 includes the cover member 22 formed of ceramics, such as alumina or the like, to cover the outer circumferential region of the substrate-receiving surface and the side surface of the stage 2. The supporting member 23 extends from the center of the bottom surface of the stage 2 downward from the processing chamber 1 through a hole formed in the bottom wall of the processing chamber 1, and the bottom end of the supporting member 23 is connected to a raising and lowering mechanism 24. Due to the raising and lowering mechanism 24, the stage 2 rises and lowers via the supporting member 23 between a transfer position at which the substrate W can be transferred as indicated by a two-dot chain line in FIG. 7, the film-forming position indicated as indicated by a solid line in FIG. 7, and a cleaning position (not shown) that is slightly higher than the film-forming position. A flange 25 is attached to the supporting member 23 below the processing chamber 1, and a bellows 26 is provided between the bottom surface of the processing chamber 1 and the flange 25. The bellows 26 is configured to separate the atmosphere in the processing chamber 1 from the outside air, and to extend and contract in accordance with the vertical movement of the stage 2.

Three (only two are illustrated) substrate supporting pins 27 are provided near the bottom surface of the processing chamber 1 to project upward from a raising and lowering plate 27a. The substrate supporting pins 27 are configured to be raised and lowered by a movement of the raising and lowering plate 27a due to a raising and lowering mechanism 28, which is provided below the processing chamber 1. As a result, the substrate supporting pins 27 can be inserted into through-holes 2a formed in the stage 2 to project and withdraw from the top surface of the stage 2. By raising and lowering the substrate supporting pins 27 in this manner, the substrate W is delivered between a substrate transfer mechanism (not shown) and the stage 2.

The shower head 3 is configured to supply the processing gas into the processing chamber 1 in a shower. The shower head 3 is formed of a metal, is provided to face the stage 2, and has a diameter substantially equal to that of the stage 2. The shower head 3 includes a body 31 fixed to the top wall 14 of the processing chamber 1, and a cap member 32 connected the underside of the body 31. A gas diffusion space 33 is formed between the body 31 and the cap member 32, and a gas inlet 36 is provided in the gas diffusion space 33 to penetrate through the center of the body 31 and the top wall 14 of the processing chamber 1. An annular projection 34 projecting downward is formed at the circumferential edge of the cap member 32, and gas holes 35 are formed in a flat surface inside the annular projection 34 of the cap member 32. The cap member 32 and the stage 2 face each other to form a processing space 37, and the film-forming raw material gas and the film-forming reaction gas are supplied through the gas inlet 36 to the processing space 37.

A gas passage 31a is formed in the body 31. The gas passage 31a extends outward beyond the outer circumference of the annular projection 34, and communicates with a plurality of gas holes 31a1 opening downward. The gas passage 31a may be formed radially or circularly. The gas passage 31a does not communicate with the gas inlet 36, and forms a passage for supplying the cleaning gas to a region 39 located outside the processing space 37 (processing space-enclosing region). The processing space-enclosing region 39 includes an annular space inside the gas exhaust duct 13.

In a state in which the stage 2 is present at the film-forming position, the processing space 37 is formed between the cap member 32 and the stage 2, and the bottom surface of the annular projection 34 and the top surface of the cover member 22 of the stage 2 are close to each other to form an annular gap 38. When the stage 2 is present at the film-forming position, the top surface of the cover member 22 is disposed at a position that is the same as or above the top surface of the partition member 16. In a state in which the stage 2 is present at the cleaning position, the top surface of the cover member 22 is disposed above the film-forming position. Therefore, the annular gap 38 (gap width G) in the state in which the stage 2 is present at the cleaning position is narrower than the gap width G in the state in which the stage 2 is present at the film-forming position.

When forming a film over the substrate W, the stage 2 may be fixed at a predetermined height. When cleaning the interior of the processing space 37, the stage 2 is raised. This causes the gap width G in the cleaning of the interior of the processing space 37 to be narrower than the gap width G at the time of the film formation.

The gas exhauster 4 is configured to exhaust the internal gas of the processing chamber 1. The gas exhauster 4 includes a gas exhaust tube 41 connected to a gas exhaust port 13b of the gas exhaust duct 13, an APC (Auto Pressure Controller) valve 42, an on-off valve 43, and a vacuum pump 44. One end of the gas exhaust tube 41 is connected to the gas exhaust port 13b of the gas exhaust duct 13, and the other end is connected to a suction port of the vacuum pump 44. The APC valve 42 and the on-off valve 43 are provided in order from the upstream side between the gas exhaust duct 13 and the vacuum pump 44. The APC valve 42 is configured to adjust the conductance of a gas exhaust passage to adjust the pressure of the processing space 37. The on-off valve 43 switches the opening/closing of the gas exhaust tube 41. During processing, the partition member 16 and the stage 2 (cover member 22) partition the interior of the processing chamber 1 into an upper space including the processing space 37 and a lower space on the rear surface side of the stage 2. Thus, the gas in the processing space 37 reaches the annular space inside the gas exhaust duct 13 through the annular gap 38 and the slit 13a, and is exhausted from the gas exhaust port 13b of the gas exhaust duct 13 through the gas exhaust tube 41 due to the vacuum pump 44 of the gas exhauster 4. The lower space has an atmosphere purged by a purge gas supply mechanism (not shown). Therefore, the gas in the processing space 37 does not flow into the lower space.

The gas supply 5 includes a film-forming raw material gas supply line L1, a film-forming reaction gas supply line L2, a first continuous N₂ gas supply line L3, and a first flash purge line L4. Further, the gas supply 5 includes a first cleaning gas line L5, a second cleaning gas line L6, a second continuous N₂ gas supply line L7, and a second flash purge line L8.

The film-forming raw material gas supply line L1 extends from a film-forming raw material gas supply source GS1, which is a source of the film-forming raw material gas, e.g., a Zyald ((C₅H₅)Zr[N(CH₃)₂]₃) gas, and is connected to a junction tube L9. The junction tube L9 is connected to the gas inlet 36. The film-forming raw material gas supply line L1 includes a mass flow controller M1, a buffer tank T1, and an on-off valve V1 in order from the raw material gas supply source GS1 side. The mass flow controller M1 is configured to control the flow rate of the Zyald ((C₅H₅)Zr[N(CH₃)₂]₃) gas flowing through the film-forming raw material gas supply line L1. The buffer tank T1 is configured to temporarily store the Zyald gas and supply the required Zyald gas in a short time. The on-off valve V1 is configured to switch supply/stop of the Zyald gas during the ALD process.

The film-forming reaction gas supply line L2 extends from the film-forming reaction gas supply source GS2, which is a supply source of the reaction gas, e.g., an O₃ gas, and is connected to the junction tube L9. The film-forming reaction gas supply line L2 includes a mass flow controller M2, a buffer tank T2, and an on-off valve V2 in order from the film-forming reaction gas supply source GS2 side. The mass flow controller M2 is configured to control the flow rate of the O₃ gas flowing through the film-forming reaction gas supply line L2. The buffer tank T2 is configured to temporarily store the O₃ gas and supply the required O₃ gas in a short time. The on-off valve V2 is configured to switch supply/stop of the O₃ gas during the ALD process.

The first continuous N₂ gas supply line L3 extends from the N₂ gas supply source GS3, which is a supply source of an N₂ gas, and is connected to the junction tube L9. Thus, the N₂ gas is supplied toward the junction tube L9 through the first continuous N₂ gas supply line L3. The first continuous N₂ gas supply line L3 always supplies the N₂ gas during the film formation by the ALD method, and the supplied N₂ gas functions as a carrier gas of the Zyald gas and O₃ gas, and as a purge gas. The first continuous N₂ gas supply line L3 includes a mass flow controller M3, an on-off valve V3, and an orifice F3 in order from the N₂ gas supply source GS3 side. The mass flow controller M3 is configured to control the flow rate of the N₂ gas flowing through the first continuous N₂ gas supply line L3. The orifice F3 is configured to suppress backflow, to the first continuous N₂ gas supply line L3, of a gas having a relatively large flow rate supplied by the buffer tanks T1, T2, and T4.

The first flash purge line L4 extends from the N₂ gas supply source GS4, which is a supply source of the N₂ gas, and is connected to the junction tube L9. Thus, the N₂ gas is supplied toward the junction tube L9 through the first flash purge line L4. The first flash purge line L4 supplies the N₂ gas only in a purge step during the film formation by the ALD method. The first flash purge line L4 includes a mass flow controller M4, a buffer tank T4, and an on-off valve V4 in order from the N₂ gas supply source GS4 side. The mass flow controller M4 is configured to control the flow rate of the N₂ gas flowing through the first flash purge line L4. The buffer tank T4 is configured to temporarily store the N₂ gas and supply the required N₂ gas in a short time. The on-off valve V4 is configured to switch supply/stop of the N₂ gas at the time of purging during the ALD process.

The first cleaning gas line L5 extends from the first cleaning gas supply source GS5, which is a supply source of the first cleaning gas, e.g., the HF gas, and is connected to a junction tube L10 and a branched tube L11 branching from the junction tube L10. The junction tube L10 is connected to the gas inlet 36. The branched tube L11 branches from the junction tube L10, and is connected to the gas passage 31a in the body 31. The first cleaning gas line L5 includes a mass flow controller M5, a buffer tank T5, and an on-off valve V5 in order from the first cleaning gas supply source GS5 side. The mass flow controller M5 is configured to control the flow rate of the HF gas flowing through the first cleaning gas line L5. The buffer tank T5 is configured to temporarily store the HF gas and supply the required HF gas in a short time. The on-off valve V5 is configured to switch supply/stop of the HF gas, which is one of the cleaning gases in the cycle cleaning process of supplying two different cleaning gases in an alternating manner.

The second cleaning gas line L6 extends from the second cleaning gas supply source GS6, which is a supply source of the second cleaning gas, e.g., the TMA gas, and is connected to the junction tube L10 and the branched tube L11. The second cleaning gas line L6 includes a mass flow controller M6, a buffer tank T6, and an on-off valve V6 in order from the second cleaning gas supply source GS6 side. The mass flow controller M6 is configured to control the flow rate of the TMA gas flowing through the second cleaning gas line L6. The buffer tank T6 is configured to temporarily store the TMA gas and supply the required TMA gas in a short time. The on-off valve V6 is configured to switch supply/stop of the TMA gas, which is the other cleaning gas in the cycle cleaning process of supplying two different cleaning gases in an alternating manner.

The second continuous N₂ gas supply line L7 extends from the N₂ gas supply source GS7, which is a supply source of the N₂ gas, and is connected to the junction tube L10 and the branched tube L11. Thus, the N₂ gas is supplied toward the junction tube L10 and the branched tube L11 through the second continuous N₂ gas supply line L7. The second continuous N₂ gas supply line L7 always supplies the N₂ gas during the cycle cleaning, and the supplied N₂ gas functions as a carrier gas of the first cleaning gas and the second cleaning gas, and as a purge gas. The second continuous N₂ gas supply line L7 includes a mass flow controller M7, an on-off valve V7, and an orifice F4 in order from the N₂ gas supply source GS7 side. The mass flow controller M7 is configured to control the flow rate of the N₂ gas flowing through the second continuous N₂ gas supply line L7. The orifice F4 is configured to suppress backflow, to the second continuous N₂ gas supply line L7, of a gas having a relatively large flow rate supplied by the buffer tanks T5, T6, and T8.

The second flash purge line L8 extends from the N₂ gas supply source GS8, which is a supply source of the N₂ gas, and is connected to the junction tube L10 and the branched tube L11. Thus, the N₂ gas is supplied toward the junction tube L10 and the branched tube L11 through the second flash purge line L8. The second flash purge line L8 supplies the N₂ gas only in a purge step during the cycle cleaning. The second flash purge line L8 includes a mass flow controller M8, a buffer tank T8, and an on-off valve V8 in order from the N₂ gas supply source GS8 side. The mass flow controller M8 is configured to control the flow rate of the N₂ gas flowing through the second flash purge line L8. The buffer tank T8 is configured to temporarily store the N₂ gas and supply the required N₂ gas in a short time. The on-off valve V8 is configured to switch supply/stop of the N₂ gas in purging in the cycle cleaning process.

The controller 6 is configured to control the operation of each component of the film-forming apparatus 100. The controller 6 includes a CPU (Central Processing Unit), a ROM (Read Only Memory), and a RAM (Random Access Memory). The CPU is configured to execute a desired process in accordance with a recipe stored in a storage area, such as a RAM or the like. The recipe includes control information set for the apparatus corresponding to process conditions. The control information may be, for example, a gas flow rate, a pressure, a temperature, and a process period. The recipe and a program used by the controller 6 may be stored, for example, in a hard disk, a semiconductor memory, or the like. The recipe or the like may be stored in a portable computer-readable storage medium, such as a CD-ROM, a DVD, or the like, which is set at a predetermined position to be read out.

### Processing method

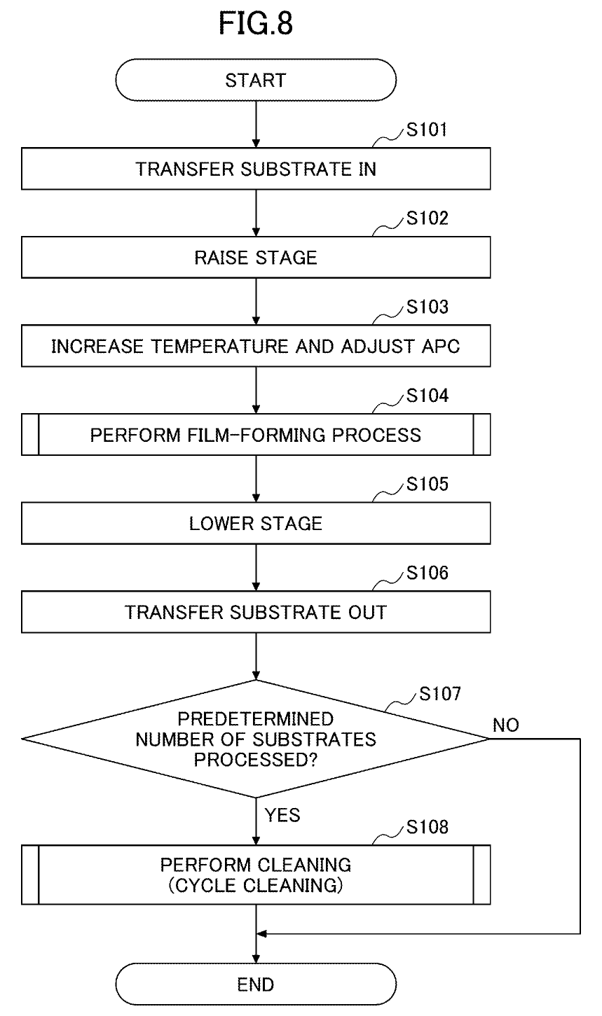

Next, a processing method performed by the film-forming apparatus 100 according to the present embodiment will be described with reference to FIG. 8. FIG. 8 is a flowchart illustrating an example of the processing method in the film-forming apparatus 100 according to the present embodiment.

In step S101, the substrate W is transferred into the processing chamber 1 of the film-forming apparatus 100. Specifically, the gate valve 12 is opened in a state in which the stage 2 heated by the heater 21 to a predetermined temperature (e.g., 200°C to 250°C) is lowered to the transfer position (indicated by a two-dot chain line in FIG. 7). Subsequently, the substrate W is transferred into the processing chamber 1 using a transfer arm (not shown) through the transfer outlet 11, and is supported by the substrate supporting pins 27. When the transfer arm is retracted from the transfer outlet 11, the gate valve 12 is closed. The substrate supporting pins 27 are lowered to place the substrate W over the stage 2.

In step S102, the controller 6 controls the raising and lowering mechanism 24 to raise the stage 2 to the film-forming position (indicated by a solid line in FIG. 7). As a result, the interior of the processing chamber 1 is partitioned between the upper space on the front surface (substrate-receiving surface) side of the stage 2 including the processing space 37, and the lower space on the rear surface side of the stage 2.

In step S103, the temperature of the substrate W over the stage 2 is increased, and the opening degree of the APC valve 42 is adjusted. That is, the temperature of the substrate W over the stage 2 is increased to a predetermined temperature by the heater 21. Also, the controller 6 controls the gas exhauster 4 to adjust the interior of the processing chamber 1 to a predetermined degree of vacuum. Subsequently, the controller 6 opens the on-off valve V3, and closes the on-off valves V1, V2, and V4 to V8. Thus, the N₂ gas is supplied into the processing space 37 from the N₂ gas supply source GS3 through the first continuous N₂ gas supply line L3, thereby increasing the pressure. Further, the controller 6 adjusts the opening degree of the APC valve 42 to achieve a desired internal pressure of the processing space 37 using a pressure sensor (not shown) configured to detect the internal pressure of the processing space 37. Thus, the controller 6 stores the internal pressure of the processing space 37 and the opening degree of the APC valve 42 in association with each other. At this time, the Zyald gas is supplied from the film-forming raw material gas supply source GS1 into the buffer tank T1, and the internal pressure of the buffer tank T1 is maintained to be substantially constant. The O₃ gas is supplied from the film-forming reaction gas supply source GS2 into the buffer tank T2, and the internal pressure of the buffer tank T2 is maintained to be substantially constant. Also, the N₂ gas is supplied from the N₂ gas supply source GS4 into the buffer tank T4, and the internal pressure of the buffer tank T4 is maintained to be substantially constant. The HF gas is supplied from the first cleaning gas supply source GS5 into the buffer tank T5, and the internal pressure of the buffer tank T5 is maintained to be substantially constant. The TMA gas is supplied from the second cleaning gas supply source GS6 into the buffer tank T6, and the internal pressure of the buffer tank T6 is maintained to be substantially constant. The N₂ gas is supplied from the N₂ gas supply source GS8 into the buffer tank T8, and the internal pressure of the buffer tank T8 is maintained to be substantially constant.

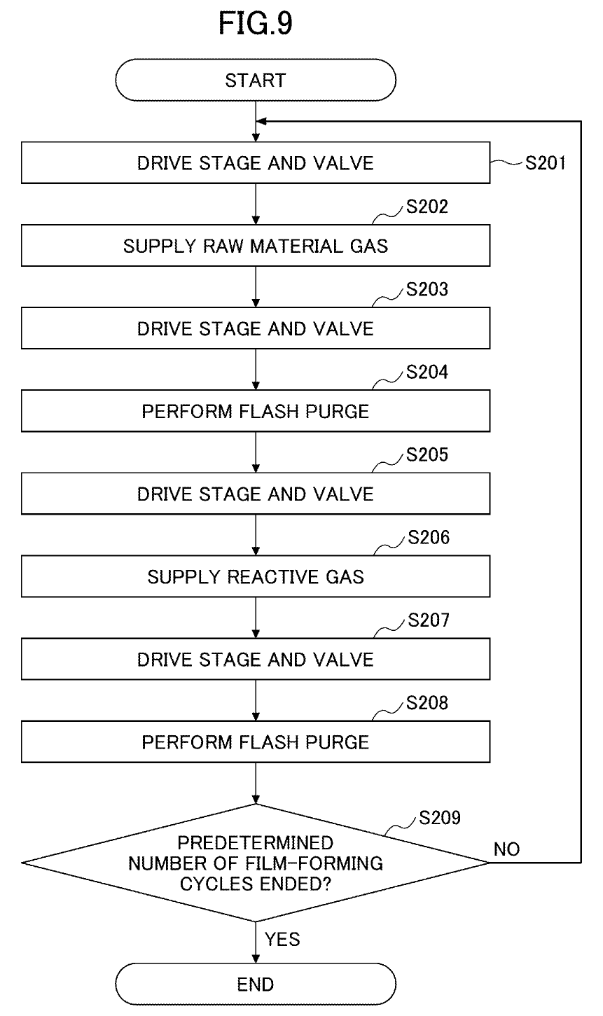

In step S104, a film-forming process is performed. In this film-forming process, a zirconium oxide film is formed over the substrate W, which will be described below with reference to FIG. 9. When the film-forming process is ended, the process proceeds to step S105.

In step S105, the controller 6 controls the raising and lowering mechanism 24 to lower the stage 2 to the transfer position.

In step S106, the substrate W is transferred out of the processing chamber 1 of the film-forming apparatus 100. Specifically, by raising the substrate supporting pins 27, the substrate W placed over the stage 2 is raised and supported by the substrate supporting pins 27. In addition, the gate valve 12 is opened. Subsequently, the substrate W is transferred out of the processing chamber 1 using the transfer arm (not shown) through the transfer outlet 11. When the transfer arm is retracted from the transfer outlet 11, the gate valve 12 is closed. Through the above procedure, the process of forming the zirconium oxide film over the substrate W in the film-forming apparatus 100 is ended.

In step S107, the controller 6 determines whether or not the film has been formed over a predetermined number of substrates W. If the controller 6 determines that the film has not been formed over the predetermined number of substrates W, the present processing method is ended without cleaning the interior of the processing chamber 1. If the controller 6 determines that the film has been formed over the predetermined number of substrates W, the process proceeds to step S108 to perform a cleaning process (cycle cleaning), thereby cleaning the interior of the processing chamber 1. Then, the present processing method is ended.

### Film-forming process

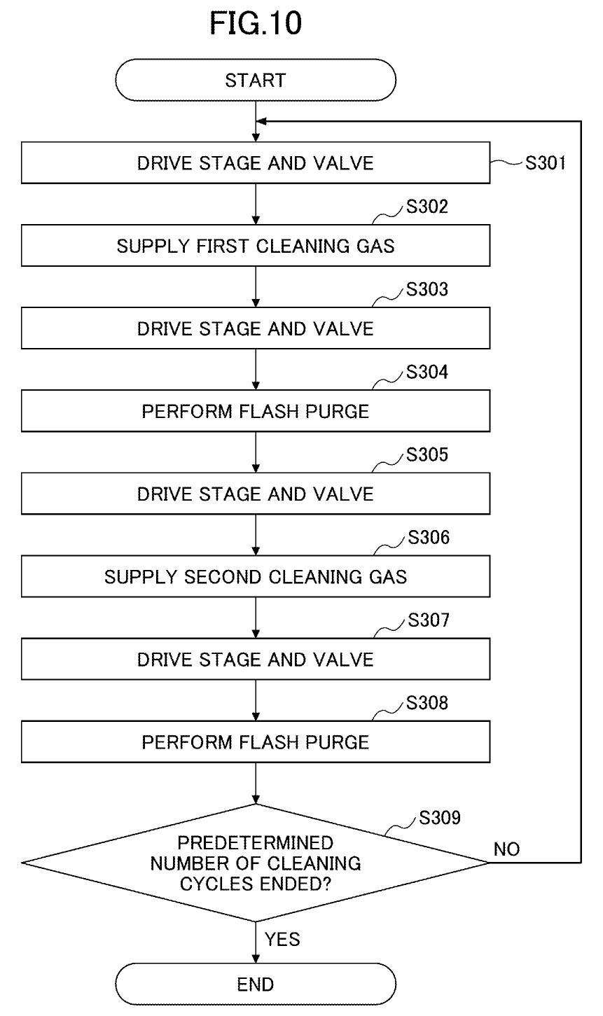

Next, the film-forming process in step S104 of FIG. 8 will be further described with reference to FIG. 9. FIG. 9 is a flowchart illustrating an example of the film-forming process in the film-forming apparatus 100 according to the present embodiment. The cleaning process (cycle cleaning) in step S108 of FIG. 8 will be described below with reference to FIG. 10.

In step S201, the controller 6 controls the raising and lowering mechanism 24 to start a raising operation to move (raise) the stage 2 to the film-forming position (see FIG. 1), and adjusts the opening degree of the APC valve 42. The adjustment of the opening degree of the APC valve is determined in accordance with the pressure described in the recipe, and the relationship between the pressure and the opening degree stored in step S103. The controller 6 sets the flow rate of the mass flow controller M3 to a predetermined flow rate set in the recipe. The carrier N₂ gas is supplied into the processing space 37 from the N₂ gas supply source GS3 through the first continuous N₂ gas supply line L3.

In step S202, the controller 6 opens the on-off valve V1 to supply the Zyald gas, i.e., the raw material gas, into the processing space 37. Here, the gap width G of the annular gap 38 is narrow (e.g., 0.5 mm). Therefore, the Zyald gas supplied into the processing space 37 is confined in the processing space 37, and thus the internal pressure of the processing space 37 increases. The supplied Zyald gas is not immediately exhausted, and the frequency of contact between the raw material gas molecules and the substrate W can be increased. Thus, the raw material gas molecules can be adsorbed onto the surface of the substrate W.

In step S203, the controller 6 closes the on-off valve V1. Also, the controller 6 controls the raising and lowering mechanism 24 to start a lowering operation to move (lower) the stage 2. This can increase the efficiency of substitution with a purge gas in the next step. However, the stage 2 may be controlled to be fixed during the film-forming process.

In step S204, the controller 6 opens the on-off valve V4 to supply the N₂ gas into the processing space 37. At this time, since the N₂ gas is supplied into the processing chamber 1 after being temporarily stored in the buffer tank T4, a relatively large flow rate can be achieved. Further, the gap width G is greater than the gap width G at the time of the supply of the raw material gas. Thus, the excess Zyald gas or the like in the processing space 37 is flash purged.

In step S205, the controller 6 closes the on-off valve V4. Also, the controller 6 controls the raising and lowering mechanism 24 to move (raise) the stage 2 to the film-forming position.

In step S206, the controller 6 sets the flow rate of the mass flow controller M3 (the flow rate of the carrier N₂ gas) to be higher than the flow rate in step S205. For example, the flow rate is returned to the flow rate in steps S201 to S204. The controller 6 opens the on-off valve V2 to supply the O₃ gas, i.e., the reaction gas, into the processing space 37. Here, the gap width G is narrow (e.g., 0.5 mm). Therefore, the O₃ gas supplied into the processing space 37 is confined in the processing space 37, and thus the internal pressure of the processing space 37 increases. The supplied O₃ gas is not immediately exhausted, and the frequency of contact between the reaction gas molecules and the substrate W can be increased, thereby achieving reaction with the raw material gas molecules adsorbed onto the surface of the substrate W.

In step S207, the controller 6 closes the on-off valve V2. Also, the controller 6 controls the raising and lowering mechanism 24 to lower the stage 2 to a purging position. This can increase the efficiency of substitution with a purge gas in the next step. However, the stage 2 may be controlled to be fixed during the film-forming process.

In step S208, the controller 6 opens the on-off valve V4 to supply the N₂ gas into the processing space 37. At this time, since the N₂ gas is supplied into the processing chamber 1 after being temporarily stored in the buffer tank T4, a relatively large flow rate can be achieved. Further, the gap width G is greater than the gap width G at the time of the supply of the reaction gas. Thus, the excess O₃ gas or the like in the processing space 37 is flash purged.

Subsequently, the controller 6 closes the on-off valve V4. Further, the controller 6 causes the flow rate of the mass flow controller M3 (the flow rate of the carrier N₂ gas) to be lower than that at the time of the supply of the reaction gas and that at the time of the flash purging (steps S206 to S208). Further, the gap width G is greater (e.g., 6 mm) than that at the time of the film formation. Therefore, the reaction product, the excess O₃ gas, the N₂ gas, and the like can be readily exhausted.

Through the process of steps S201 to S208, one cycle of the ALD process is ended.

In step S209, the controller 6 determines whether or not a predetermined number of film-forming cycles has been ended. If the predetermined number of film-forming cycles has not been ended, the process of steps S201 to S208 is repeated until the end of the predetermined number of film-forming cycles. If the predetermined number of film-forming cycles has been ended, the film-forming process is ended.

### Cleaning process (cycle cleaning)

Next, the cleaning process (cycle cleaning) of step S108 of FIG. 8 will be further described with reference to FIG. 10. FIG. 10 is a flowchart illustrating an example of the cleaning process (cycle cleaning) in the film-forming apparatus 100 according to the present embodiment.

In step S301, the controller 6 controls the raising and lowering mechanism 24 to start a raising operation to move (raise) the stage 2 to the cleaning position, and adjusts the opening degree of the APC valve 42. Here, the cleaning position is slightly higher than the film-forming position, and the gap width G of the annular gap 38 is narrower (e.g. less than 0.5 mm) than that at the time of the film formation.

The controller 6 sets the flow rate of the mass flow controller M7 to a predetermined flow rate set in the recipe. The carrier N₂ gas is supplied from the N₂ gas supply source GS7 into the processing space 37 through the second continuous N₂ gas supply line L7.

In step S302, the controller 6 opens the on-off valve V5 to supply the HF gas, which is an example of the first cleaning gas, into the processing space 37 through the junction tube L10 and the gas inlet 36. Here, the gap width G is narrow (e.g. less than 0.5 mm). Therefore, the HF gas supplied into the processing space 37 is confined in the processing space 37, and thus the internal pressure of the processing space 37 increases. The supplied HF gas is not immediately exhausted, and the frequency of contact between the HF gas and the parts in the processing space 37, such as the inner wall and the like, can be increased, thereby accelerating modification of the surface of the parts in the processing space 37.

Further, the controller 6 supplies the HF gas, i.e., the first cleaning gas, from the gas holes 31a1 to the processing space-enclosing region 39, located outside the processing space 37 (annular projection 34), through the junction tube L10, the branched tube L11, and the gas passage 31a. This modifies the zirconium oxide film adhering to the surface of the parts in the processing space-enclosing region 39.

In step S303, the controller 6 closes the on-off valve V5. Further, the controller 6 controls the raising and lowering mechanism 24 to start a lowering operation to move (lower) the stage 2. This can increase the efficiency of substitution with a purge gas in the next step. However, the stage 2 may be controlled to be fixed at the cleaning position during the cleaning process.

In step S304, the controller 6 opens the on-off valve V8 to supply the N₂ gas into the processing space 37. At this time, since the N₂ gas is supplied into the processing chamber 1 after being temporarily stored in the buffer tank T8, a relatively large flow rate can be achieved. Further, the gap width G is greater than the gap width G at the time of the supply of the HF gas. As a result, the excess HF gas or the like in the processing space 37 is flash purged.

In step S305, the controller 6 closes the on-off valve V8. Also, the controller 6 controls the raising and lowering mechanism 24 to move (raise) the stage 2 to the cleaning position.

In step S306, the controller 6 causes the flow rate of the mass flow controller M7 (the flow rate of the carrier N₂ gas) to be higher than the flow rate in step S305. For example, the flow rate is returned to the flow rate in steps S301 to S304. The controller 6 opens the on-off valve V6 to supply the TMA gas, i.e., an example of the second cleaning gas, into the processing space 37. Here, the gap width G is narrow (e.g. less than 0.5 mm). Therefore, the TMA gas supplied into the processing space 37 is confined in the processing space 37, and thus the internal pressure of the processing space 37 increases. The supplied TMA gas is not immediately exhausted, and the frequency of contact between the TMA gas and the parts in the processing space 37, such as the inner wall and the like, can be increased. Thus, the modified layer of the zirconium oxide film adhering to the surfaces of the parts in the processing space 37 can be removed through etching, and the interior of the processing space 37 can be cleaned.

Further, the controller 6 supplies the TMA gas from the gas holes 31a1 to the processing space-enclosing region 39 through the junction tube L10, the branched tube L11, and the gas passage 31a. Thus, the modified layer of the zirconium oxide film adhering to the surfaces of the parts in the processing space-enclosing region 39 can be removed through etching, and the processing space-enclosing region 39 can be cleaned.

In step S307, the controller 6 closes the on-off valve V6. Also, the controller 6 controls the raising and lowering mechanism 24 to lower the stage 2 to the purging position. This can increase the efficiency of substitution with a purge gas in the next step. However, the stage 2 may be controlled to be fixed at the cleaning position during the cleaning process.

The controller 6 opens the on-off valve V8 to supply the N₂ gas into the processing space 37. At this time, since the N₂ gas is supplied into the processing chamber 1 after being temporarily stored in the buffer tank T8, a relatively large flow rate can be achieved. The gap width G is greater than the gap width G at the time of the supply of the reaction gas. Thus, the excess TMA or the like in the processing space 37 is flash purged.

Subsequently, the controller 6 closes the on-off valve V8. Also, the controller 6 causes the flow rate of the mass flow controller M7 (the flow rate of the carrier N₂ gas) to be lower than that at the time of the supply of the first cleaning gas and that at the time of the flash purging (steps S306 to S308). Further, the gap width G is greater (e.g., 6 mm) than the gap width G at the time of the film formation. Therefore, the reaction product, the excess TMA gas, the N₂ gas, and the like can be readily exhausted.

Through the process of steps S301 to S308, one cycle of the cycle cleaning process of supplying two different cleaning gases in an alternating manner is ended, similar to ALE for a substrate.

In step S309, the controller 6 determines whether or not the predetermined number of cleaning cycles is ended. If the predetermined number of cleaning cycles has not been ended, the process of steps S301 to S308 is repeated until the end of the predetermined number of cleaning cycles. If the predetermined number of cleaning cycles has been ended, the cycle cleaning is ended.

As described above, the processing method performed in the film-forming apparatus 100 supplies, during the film formation, the film-forming raw material gas from the film-forming raw material gas supply source GS1 and the film-forming reaction gas from the film-forming reaction gas supply source GS2 to the processing space 37 in an alternating manner. This forms a film over the substrate W by the ALD method. However, the film-forming raw material gas and the film-forming reaction gas may be simultaneously supplied to the processing space 37.

Examples of the film-forming raw material gas include TiCl₄, Zyald((C₅H₅)Zr[N(CH₃)₂]₃), Hyzld(C₁₁H₂₃HfN₃), HOC(Hf(C₅H₅)[N(CH₃)₂]₃), SiH₄, NH₄, DCS, TMA, HCD, and O₃. Examples of the type of the film to be formed include TiAlN, TiAlC, HfSiO, ZrHfSiO, HfSiON, ZrO, HfO, and AlO.

After the formation of the predetermined number of films and then the transfer of the substrate W out, the first cleaning gas from the first cleaning gas supply source GS5 and the second cleaning gas from the second cleaning gas supply source GS6 are supplied to the processing space 37 in an alternating manner. This can perform the ALE-like cycle cleaning on the interior of the processing space 37.

The film-forming apparatus 100 may include: the buffer tank T5 (first buffer tank) disposed in the first cleaning gas line L5 connecting the processing chamber 1 and the first cleaning gas supply source GS5; and the buffer tank T6 (second buffer tank) disposed in the second cleaning gas line L6 connecting the processing chamber 1 and the second cleaning gas supply source GS6. In this case, the first cleaning gas temporarily stored in the buffer tank T5 and the second cleaning gas temporarily stored in the buffer tank T6 are supplied to the processing space 37 in an alternating manner. However, the film-forming apparatus 100 may supply the cleaning gases without using the buffer tanks.

When cleaning the interior of the processing space 37, the first cleaning gas and the second cleaning gas may be supplied, in an alternating manner, to the interior of the processing space 37 and the processing space-enclosing region 39 from the gas holes 35 formed in the cap member 32 and the gas holes 31a1 formed in the body 31. This can clean the interior of the processing space 37 and the processing space-enclosing region 39 located outside the processing space 37.

The pressure of the processing space 37 in the cleaning of the interior of the processing space 37 is about several hundred Torr, and the pressure of the processing space 37 in the formation of the film over the substrate W is about 10 Torr. Therefore, the pressure of the processing space 37 in the cleaning of the interior of the processing space 37 is higher than the pressure of the processing space 37 in the formation of the film over the substrate W.

### Effects

According to the cleaning method (cycle cleaning) according to the present embodiment, when the fill tank is provided, a gas having a pressure equal to or higher than a predetermined pressure is stored in the fill tank, thereby supplying the stored gas into the processing chamber 1 at the pressure equal to or higher than the predetermined pressure. This can switch between the first cleaning gas and the second cleaning gas at a high speed. As a result, the period per cycle of repeatedly supplying the first cleaning gas and the second cleaning gas in an alternating manner can be 2 seconds or less, enabling high-speed cycle cleaning. Thus, when using the high-speed cycle cleaning, the period per cycle can be reduced to 0.5 seconds or less, and thus etching can be performed by 120 Å in one minute and by 7,200 Å in one hour. Similarly, at the time of the film formation, it is possible to perform the film formation using high-speed ALD, in which the film-forming raw material gas and the film-forming reaction gas are switched at a high speed. Although the processing space 37 at the time of the film formation is a region enclosed by the cap member 32 and the stage 2, a high-k film, such as a zirconium oxide film or the like, adhering to the interior of the processing space 37 can be etched (cleaned). This can extend a period until replacement of a liner part, thereby increasing productivity.

The cleaning method and the film-forming apparatus 100 according to the embodiments disclosed herein should be considered to be illustrative and non-limiting in all respects. The embodiments can be modified and improved in various forms without departing from the scope and intent of the attached claims. The matters described in the above embodiments may be employed in other configurations if there is no contradiction, and may be combined together if there is no contradiction.

The above embodiments have been described using the case in which the film-forming apparatus 100 is a single-wafer type apparatus configured to process wafers one by one. However, the present disclosure is not limited to this. For example, the film-forming apparatus 100 may be a batch type apparatus configured to process many wafers at one time, or may be a semi-batch type apparatus configured to process a plurality of wafers.

According to one aspect, it is possible to clean parts in a film-forming apparatus while suppressing damage to the parts.

What is claimed is:

1. A cleaning method for a film-forming apparatus, including a film-forming raw material gas supply source, a film-forming reaction gas supply source, a first cleaning gas supply source, a second cleaning gas supply source, a stage that is provided in a processing chamber and is configured to receive a substrate and to be elevatable, and a cap member that is provided in the processing chamber and faces the stage to form a processing space, the cleaning method comprising:
forming a film over the substrate by supplying, to the processing space, a film-forming raw material gas from the film-forming raw material gas supply source and a film-forming reaction gas from the film-forming reaction gas supply source; and
cleaning an interior of the processing space by transferring the substrate out of the processing chamber after the formation of the film, and supplying, to the processing space, a first cleaning gas from the first cleaning gas supply source and a second cleaning gas from the second cleaning gas supply source, in an alternating manner.

2. The cleaning method according to claim 1, wherein
the film is formed over the substrate by supplying, to the processing space, the film-forming raw material gas from the film-forming raw material gas supply source and the film-forming reaction gas from the film-forming reaction gas supply source, in an alternating manner.

3. The cleaning method according to claim 1, wherein
the film-forming apparatus includes a first buffer tank disposed in a first cleaning gas line connecting the processing chamber and the first cleaning gas supply source, and a second buffer tank disposed in a second cleaning gas line connecting the processing chamber and the second cleaning gas supply source, and
the first cleaning gas temporarily stored in the first buffer tank and the second cleaning gas temporarily stored in the second buffer tank are supplied to the processing space in an alternating manner.

4. The cleaning method according to claim 1, wherein
the stage during the cleaning of the interior of the processing space is raised, and a gap between the stage and the cap member during the cleaning of the interior of the processing space is caused to be narrower than a gap between the stage and the cap member in the formation of the film over the substrate.

5. The cleaning method according to claim 1, wherein
the film-forming apparatus includes a shower head including a body and the cap member, and
the first cleaning gas and the second cleaning gas are supplied, in an alternating manner, from a gas hole formed in the cap member and a gas hole formed in the body, to the processing space and a processing space-enclosing region located outside the processing space, thereby cleaning the interior of the processing space and the processing space-enclosing region.

6. The cleaning method according to claim 1, wherein
in a case in which the film formed over the substrate is a high-k film and the high-k film is an oxide film, the first cleaning gas is a gas including fluorine.

7. The cleaning method according to claim 6, wherein
in a case in which the film formed over the substrate is alumina, a combination of the first cleaning gas and the second cleaning gas is that:
the first cleaning gas is an HF gas, and the second cleaning gas is a TMA gas, a DMAC gas, an Sn(acac)₂ gas, a gas mixture of a TMA gas and a DMAC gas, or a gas mixture of a TMA gas, a DMAC gas, an Sn(acac)₂ gas, and an SiCl₄ gas;
the first cleaning gas is a CHF₃ gas, and the second cleaning gas is a TMA gas; or
the first cleaning gas is a gas mixture of an HF gas and an SF₄ gas, and the second cleaning gas is an Sn(acac)₂ gas.

8. The cleaning method according to claim 6, wherein
in a case in which the film formed over the substrate is a hafnium oxide, a combination of the first cleaning gas and the second cleaning gas is that:
the first cleaning gas is an HF gas, and the second cleaning gas is a DMAC gas or a gas mixture of a DMAC gas and a TiCl₄ gas; or
the first cleaning gas is a gas mixture of an HF gas, an XeF₂ gas, and an SF₄ gas, and the second cleaning gas is a gas mixture of a DMAC gas and a TiCl₄ gas.

9. The cleaning method according to claim 6, wherein
in a case in which the film formed over the substrate is a zirconium oxide, a combination of the first cleaning gas and the second cleaning gas is that:
the first cleaning gas is an HF gas, and the second cleaning gas is a DMAC gas, a gas mixture of a DMAC gas and a TiCl₄ gas, or a gas mixture of a DMAC gas, a TMA gas, an Sn(acac)₂ gas, and an SiCl₄ gas; or
the first cleaning gas is a WF₆ gas, and the second cleaning gas is a DMAC gas.

10. The cleaning method according to claim 6, wherein
in a case in which the film formed over the substrate is an IGZO, a combination of the first cleaning gas and the second cleaning gas is that:
the first cleaning gas is an HF gas, and the second cleaning gas is a DMAC gas.

11. The cleaning method according to claim 1, wherein
the film formed over the substrate is a metal film, and
the first cleaning gas is a gas including oxygen or a gas including chlorine.

12. The cleaning method according to claim 11, wherein
in a case in which the film formed over the substrate is Co,
the first cleaning gas is a Cl₂ gas and the second cleaning gas is a gas mixture of an Hhfac gas and an Hacac gas, or the first cleaning gas is an O₂ gas and the second cleaning gas is an Hfac gas.

13. The cleaning method according to claim 11, wherein
in a case in which the film formed over the substrate is Cu,
the first cleaning gas is an O₃ gas, and the second cleaning gas is an Hfac gas.

14. The cleaning method according to claim 11, wherein
in a case in which the film formed over the substrate is Fe,
the first cleaning gas is a Cl₂ gas, and the second cleaning gas is an Hacac gas.

15. The cleaning method according to claim 11, wherein
in a case in which the film formed over the substrate is Mo,
the first cleaning gas is an O₃ gas, and the second cleaning gas is a BCl₃ gas.

16. The cleaning method according to claim 11, wherein
in a case in which the film formed over the substrate is Ni,
the first cleaning gas is an O₂ gas, and the second cleaning gas is an Hhfac gas.

17. The cleaning method according to claim 1, wherein
the first cleaning gas and the second cleaning gas are repeatedly supplied in an alternating manner, and a period per cycle of the repeated supply is 2 seconds or less.

18. The cleaning method according to claim 1, wherein
a pressure of the processing space in the cleaning of the interior of the processing space is higher than a pressure of the processing space in the formation of the film over the substrate.

19. A film-forming apparatus, comprising:
a film-forming raw material gas supply source;
a film-forming reaction gas supply source;
a first cleaning gas supply source;
a second cleaning gas supply source;
a stage that is provided in a processing chamber and is configured to receive a substrate and to be elevatable;
a cap member that is provided in the processing chamber and faces the stage to form a processing space;
a first cleaning gas line connecting the processing chamber and the first cleaning gas supply source;
a second cleaning gas line connecting the processing chamber and the second cleaning gas supply source; and
a controller including a memory and a processor coupled to the memory, wherein
the controller is configured to:
form a film over the substrate by supplying, to the processing space, a film-forming raw material gas from the film-forming raw material gas supply source and a film-forming reaction gas from the film-forming reaction gas supply source, and
clean an interior of the processing space by transferring the substrate out of the processing chamber after the formation of the film, and supplying, to the processing space, a first cleaning gas from the first cleaning gas supply source through the first cleaning gas line and a second cleaning gas from the second cleaning gas supply source through the second cleaning gas line, in an alternating manner.
